(19) United States
(12) Patent Application Publication
(10) Pub. No.: US 2006/0114741 A1
(43) Pub. Date: Jun. 1, 2006

(54) Program invocation methods and devices utilizing the same

(75) Inventor: Sheng Kai Hsu, Yilan County (TW)

Correspondence Address: QUINTERO LAW OFFICE, 1617 BROADWAY, 3RD FLOOR, SANTA MONICA, CA, 90404, US

(73) Assignee: MITAC TECHNOLOGY CORP., HSIN-CHU HSIEN (TW)

(21) Appl. No.: 11/100,009

(22) Filed: Apr. 5, 2005

(30) Foreign Application Priority Data
Nov. 26, 2004 (TW) TW93136516

(51) Int. Cl. G11C 8/02

(52) U.S. Cl. 365/232

(57) ABSTRACT

An electronic device comprises a first operating system, another second operating system, a first application, an emulator, a switch, and a processor. The first application is executable on the second operating system. The emulator imitates the runtime environment of the second operating system while the first operating system is running. The switch generates a first signal. The processor determines to which application the switch corresponds based on the first signal while the first operating system is running. When determining that the first application corresponds to the switch, the processor automatically executes the first application utilizing the emulator, whereby the first application is executable while the first operating system is running.

### BACKGROUND

The invention relates to computer techniques, and in particular, to program invocation methods and devices utilizing the same.

Unlike general-purpose computers, an embedded system typically has a micro operating system (OS) stored on a chip rather than on a hard disk. Exemplary embedded systems comprise televisions, disc players, radios, information appliance, and others. Linux is a suitable OS for embedded system as it has the advantages of small kernel, short boot time, and stable performance.

In the case of an embedded system integrated into a personal computer, a separate micro OS (e.g. Linux) of the embedded system can boot quickly and serve as a multimedia player without requiring booting of the major OS (such as Windows) of the personal computer. If an application of the major OS is required execution, the personal computer must boot with the major OS while the micro OS of the embedded system is running. The booting procedure, however, is time consuming.

### SUMMARY

Accordingly, program invocation methods and devices utilizing the same are provided. An exemplary embodiment of the electronic device comprises a first operating system, another second operating system, a first application, an emulator, a switch, and a processor. The first application is executable by the second operating system. The emulator imitates the runtime environment of the second operating system in the runtime environment of the first operating system. The switch generates a first signal. The processor determines to which application the switch corresponds to in the runtime environment of the first operating system based on the first signal. Upon determining that the first application corresponds to the switch, the processor automatically executes the first application utilizing the emulator, whereby the first application is executable while the first operating system is running.

An exemplary embodiment of the program invocation method is implemented in an electronic device comprising a first operating system, another second operating system, a first application, an emulator, a switch, and a processor. The first application is executable on the second operating system. The emulator imitates the runtime environment of the second operating system in the runtime environment of the first operating system. When the switch generates a first signal, the processor determines to which application the switch corresponds in the runtime environment of the first operating system based on the first signal. Upon determining that the first application corresponds to the switch, the processor automatically executes the first application utilizing the emulator, whereby the first application is executable while the first operating system is running.

An exemplary embodiment of the program invocation method is implemented in an electronic device comprising a first operating system, another second operating system, a first application, an emulator, and a processor. The first application is executable by the second operating system. The emulator imitates the runtime environment of the second operating system in the runtime environment of the first operating system. When a Graphical User Interface (GUI) element of the first operating system is selected, a first signal is generated. The processor determines to which application the GUI element corresponds in the runtime environment of the first operating system based on the first signal. Upon determining that the first application corresponds to the GUI element, the processor automatically executes the first application utilizing the emulator, whereby the first application is executable while the first operating system is running.

### DESCRIPTION OF THE DRAWINGS

The invention can be more fully understood by reading the subsequent detailed description and examples with references made to the accompanying drawings, wherein:

FIG. 1 is a block diagram of an exemplary embodiment of an electronic device;

FIG. 2 is a flowchart of an exemplary embodiment of the program invocation method; and

FIG. 3 is a flowchart of exemplary program termination steps.

### DETAILED DESCRIPTION

Program invocation methods and devices utilizing the same are provided, whereby one of two different OS installed on a computer can invoke an application of the other OS in response to the operation of a switch.

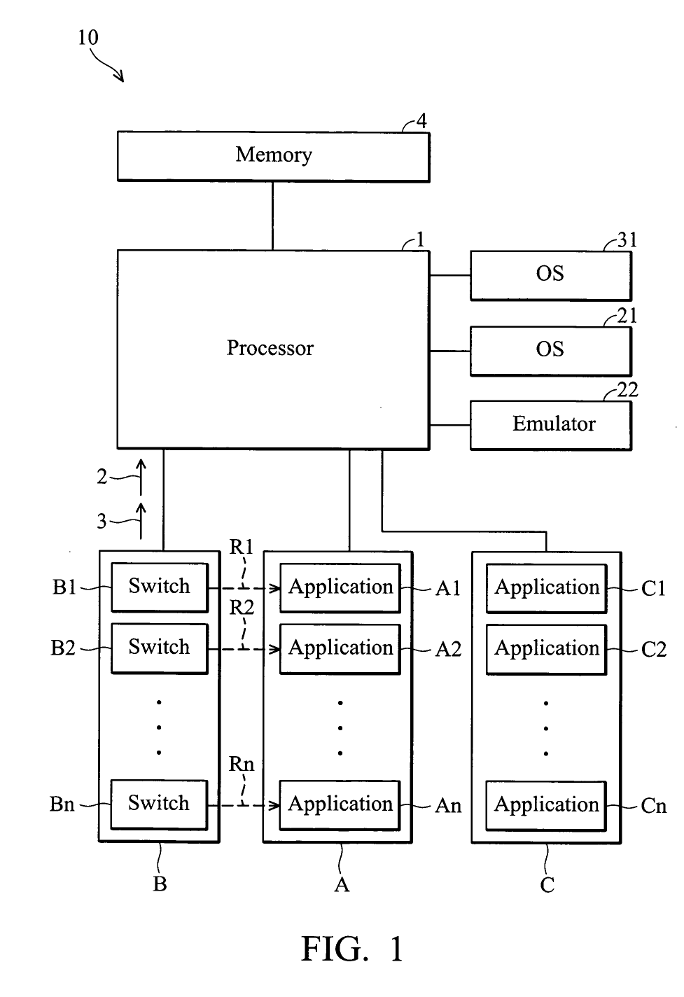

In computer 10 shown in FIG. 1, processor 1 is coupled to input device B, applications A1˜An, applications C1˜Cn, memory 4, OS 21, emulator 22, and OS 31. For the sake of simplicity, applications A1˜An are represented by group A, and applications C1˜Cn are represented by group C. For example, OS 21 is dedicated to multimedia functions, such as TV or radio reception, and CD and/or DVD playback. Applications A1˜An and C1˜Cn, OS 21, emulator 22, and OS 31 can be stored in different storage devices (such as hard disks, chips, or flash memories), or different partitions of a hard disk. Some applications can be stored in the same partition. For example, emulator 22 and OS 21 may be stored in a partition while OS 31 and applications A1˜An are stored in another partition. Computer 10 may be an embedded system with chips storing OS 21 and/or 31.

Os 31 is different from OS 21. Applications A1˜An are designed to run on OS 31 while applications C1˜Cn are designed to run on OS 21. Emulator 22 imitates the runtime environment of OS 31 during run time of OS 21. For example, OS 21 and 31 may be respectively the Linux and the Windows OS, and emulator 22 can be the Wine program simulating Windows OS and enabling certain applications of the Windows OS executable in the the runtime environment of the Linux OS.

Switches B1˜Bn can be operated to generate signals. Processor 1 identifies the signals. Each switch B1˜Bn corresponds to one of the applications A1˜An, wherein the correspondence therebetween represented by relationships R1˜Rn shown in FIG. 1 may be stored in a storage device or a memory of computer 10. Switches B1˜Bn may be buttons or other input devices. For example, a switch Bi (wherein i is an integer, and 1≦i≦n) of switches B1˜Bn has two states, enters to a first state when pressed once, and returns to a second state when pressed again. The switch Bi generates a program invocation signal (such as signal 2 in FIG. 1) when changing from the second state to the first state, and generates a program termination signal (such as signal 3 in FIG. 1) when changing from the first state to the second state. In another example, a switch Bj (wherein j is an integer, and 1≦j≦n) of switches B1˜Bn generates a program invocation signal when changing its position for the first time, and generates a program termination signal when changing its position for the second time. Note that OS 21 may also provide a plurality of Graphical User Interface (GUI) elements corresponding to applications A1˜An. When one of the GUI elements is selected, processor 1 automatically generates a signal for initiating or terminating an application corresponding to the GUI element.

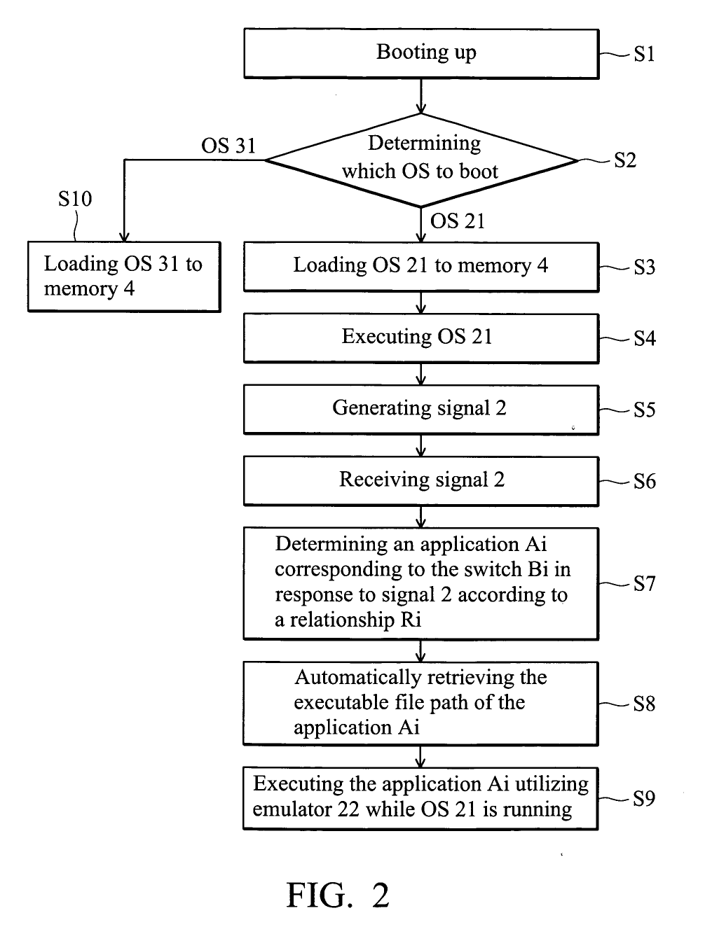

An exemplary program invocation procedure is now described in detail with reference to FIG. 2.

First, when computer 10 boots up (step S1), which OS is to be booted is determined (step S2). When determining to boot OS 31, processor 1 loads OS 31 to memory 4 (step S10). When determining to boot OS 21, processor 1 loads OS 21 to memory 4 (step S3) and executes OS 21 (step S4).

The switch Bi of switches B1˜Bn is operated to generate signal 2 (step S5). Processor 1 receives signal 2 (step S6), and automatically performs the following steps: determining an application Ai corresponding to the switch Bi in response to signal 2 according to a relationship Ri of relationships R1˜Rn (step S7); retrieving the executable file path of the application Ai (step S8); executing the application Ai in the runtime environment of OS 21 utilizing emulator 22 (step S9). Table 1 is an example of relationships R1˜Rn:

TABLE 1

| | Signal Identification | Executable File Path |
|---|---|---|
| Relationship | (ID) number | (file name included) |
| R1 | ID number I1 | Path P1 |
| R2 | ID number I2 | Path P2 |
| . . . | . . . | . . . |
| Rn | ID number In | Path Pn |

Table 1 may be stored in a storage device of computer 10. When switch B2 generates signal 2 comprising ID number I2, processor 1 receives signal 2, extracts ID number I2 therefrom in steps S7 and S8, searches table 1 for ID number I2, and retrieves relationship R2 and executable file path P2 of application A2 corresponding to switch B2. In step S9, processor 1 executes application A2 utilizing emulator 22 based on path P2. For example, application A2 is a network communication program, such as a web browser or others.

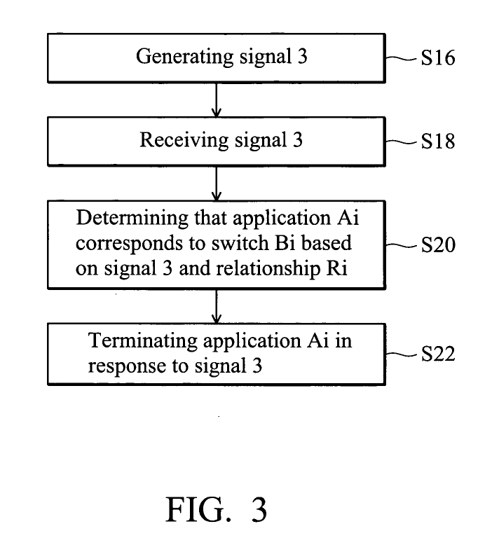

An exemplary application termination process is detailed in the following with reference to FIG. 3.

When switch Bi generates signal 3 while application Ai initiated in step 9 is running (step S16), processor 1 receives signal 3 (step S18), determines that application Ai corresponds to switch Bi based on signal 3 and relationship Ri of relationships R1˜Rn (step S20), and terminates application Ai in response to signal 3 (step S22).

For example, when application A2 is still in execution, processor 1 terminates application A2 in response to signal 3 generated by switch B2. Similarly, switches B1˜Bn can respectively trigger corresponding applications A1˜An.

Note that two separate buttons respectively triggering and terminating an application can be used to replace a single switch described previously.

While the invention has been described by way of example and in terms of preferred embodiment, it is to be understood that the invention is not limited thereto. To the contrary, it is intended to cover various modifications and similar arrangements (as would be apparent to those skilled in the art) . Therefore, the scope of the appended claims should be accorded the broadest interpretation so as to encompass all such modifications and similar arrangements.

What is claimed is:

1. A electronic device, comprising:
a first operating system;
a second operating system different from the first operating system;
a first application executable by the second operating system;
an emulator imitating the runtime environment of the second operating system while the first operating system is running;
a switch generating a first signal;
a processor determining to which application the switch corresponds while the first operating system is running based on the first signal, and, upon determining that the first application corresponds to the switch, automatically executing the first application utilizing the emulator, whereby the first application is executable while the first operating system is running.

2. The device as claimed in claim 1, wherein the processor terminates the first application according to a second signal generated by the switch.

3. The device as claimed in claim 1, wherein the switch comprises a button.

4. The device as claimed in claim 1, wherein the first operating system is dedicated to playing multimedia files.

5. The device as claimed in claim 1, wherein the electronic device stores the correspondence of the switch and the first application and executes the first application based on the first signal and the correspondence.

6. The device as claimed in claim 1, wherein the processor automatically retrieves executable file path of the first application.

7. The device as claimed in claim 1, wherein the first operating system is the Linux operating system.

8. The device as claimed in claim 1, wherein the second operating system is the Windows operating system.

9. The device as claimed in claim 1, wherein the emulator is the Wine program.

10. A program invocation method, implemented in an electronic device comprising a first operating system, another second operating system, a first application, an emulator, a switch, and a processor, wherein the first application is executable on the second operating system, and the emulator imitates the runtime environment of the second operating system in the runtime environment of the first operating system, comprising:
executing the first operating system by the processor;
when the switch generates a first signal, determining, by the processor, to which application the switch corresponds while the first operating system is running; and
when the first application corresponds to the switch, automatically executing the first application utilizing the emulator, whereby the first application is executable while the first operating system is running.

11. The method as claimed in claim 10, wherein the processor terminates the first application according to a second signal generated by the switch.

12. The method as claimed in claim 10, wherein the electronic device stores the correspondence of the switch and the first application, the method further comprising executing the first application based on the first signal.

13. The method as claimed in claim 10, wherein the processor automatically retrieves executable file path of the first application.

14. The method as claimed in claim 10, wherein the first operating system is the Linux operating system.

15. The method as claimed in claim 10, wherein the second operating system is the Windows operating system.

16. The method as claimed in claim 10, wherein the emulator is the Wine program.

17. A program invocation method, implemented in an electronic device comprising a first operating system, another second operating system, a first application, an emulator, and a processor, wherein the first application is executable on the second operating system, and the emulator imitates the runtime environment of the second operating system while the first operating system is running, comprising:
executing the first operating system by the processor;
when a Graphical User Interface (GUI) element of the first operating system is selected, generating a first signal;
determining, by the processor, to which application the GUI element corresponds while the first operating system is running based on the first signal; and
when the first application corresponds to the GUI element, automatically executing the first application utilizing the emulator, whereby the first application is executable while the first operating system is running.

18. The method as claimed in claim 17, wherein the first operating system is the Linux operating system.

19. The method as claimed in claim 17, wherein the second operating system is the Windows operating system.

20. The method as claimed in claim 17, wherein the emulator is the Wine program.
